(19) United States
(12) Patent Application Publication
(10) Pub. No.: US 2020/0072887 A1
(43) Pub. Date: Mar. 5, 2020

(54) PHASE GROUP ESTIMATION DEVICE, PHASE GROUP ESTIMATION METHOD, AND RECORDING MEDIUM

(71) Applicant: Mitsubishi Electric Corporation, Chiyoda-ku, Tokyo (JP)

(72) Inventors: Hirohisa FURUTA, Tokyo (JP); Shoichi KITAMURA, Tokyo (JP)

(73) Assignee: Mitsubishi Electric Corporation, Chiyoda-ku, Tokyo (JP)

(21) Appl. No.: 16/493,635

(22) PCT Filed: Mar. 30, 2017
(86) PCT No.: PCT/JP2017/013411

§ 371 Date: Sep. 12, 2019

(51) Int. Cl. G01R 29/18; G01R 11/40

(52) U.S. Cl. CPC G01R 29/18; G01R 11/25; G01R 11/40

(57) ABSTRACT

A phase group estimation device according to the present invention includes: a data acquirer that acquires data transmitted from a smart meter; a storage that stores equipment information indicating a correspondence between the smart meter and a pole-mounted transformer corresponding to the smart meter; and a phase group estimator that classifies processing sections into phase groups based on the equipment information and the data. Each of the processing sections is a section corresponding to a pole-mounted transformer, and each of the phase groups is powered by the same phase of a distribution line.

### FIELD

The present invention relates to a phase group estimation device, a phase group estimation method, and a recording medium for estimating the phase group to which each section of a distribution line belongs.

### BACKGROUND

Conventionally, a multi-phase alternating current distribution system is not generally managed in terms of to which phase of the distribution line each pole-mounted transformer is connected. Hereinafter, the pole-mounted transformers and loads connected to the same phase are referred to as the pole-mounted transformers and loads that belong to the same phase group, respectively. For example, in a three-phase three-wire distribution line, each pole-mounted transformer is connected in any of the three connection configurations: the first connection configuration in which a pole-mounted transformer is connected to the U- and V-phases, the second connection configuration in which a pole-mounted transformer is connected to the V- and W-phases, and the third connection configuration in which a pole-mounted transformer is connected to the W- and U-phases. The connection configuration of each pole-mounted transformer depends on the individual installation work for the pole-mounted transformer, and is not managed as a whole. Therefore, the connection configuration of each load connected to each pole-mounted transformer is also not managed. Therefore, in the event of a disconnection in some phase of the distribution line, it is difficult to identify the extent of the influence of the disconnection.

For this reason, it is desirable to grasp which phase of the distribution line a pole-mounted transformer is connected to. As a technique for grasping which phase of the distribution line a pole-mounted transformer is connected to, for example, Patent Literature 1 discloses a technique of determining the phase a pole-mounted transformer is connected to based on the measurement values of the voltage of the high-voltage distribution line and the measurement values of power consumption provided by smart meters.

### CITATION LIST

### Patent Literature

Patent Literature 1: Japanese Patent Application Laid-open No. 2012-198033

### SUMMARY

### Technical Problem

The above-mentioned conventional technique determines which phase of the distribution line a pole-mounted transformer is connected to using the measurement values of the voltage of the high-voltage distribution line measured by a section switch with a built-in sensor or the like. However, the number of points where the voltage of the high-voltage distribution line is measured is limited, and there may not be enough measurement points to determine which phase of the distribution line a pole-mounted transformer is connected to. Moreover, in order to increase the number of points where the voltage of the high-voltage distribution line is measured, generally, a network different from the network for collecting measurement values from smart meters is employed. Therefore, large-scale equipment is required for using the both types of measurement values.

The present invention has been made in view of the above, and an object thereof is to obtain a phase group estimation device, a phase group estimation method, and a phase group estimation program capable of estimating which pole-mounted transformers belong to the same phase group without requiring measurement values of the voltage of the high-voltage distribution line.

### Solution to Problem

In order to solve the problems described above and achieve the object, a phase group estimation device according to the present invention includes: a data acquirer that acquires data transmitted from a measuring device capable of measuring a voltage of a first distribution line; and a storage that stores equipment information indicating a correspondence between the measuring device and an instrument connected to the first distribution line corresponding to the measuring device and connected to a second distribution line. The phase group estimation device according to the present invention further includes a phase group estimator that classifies processing sections into phase groups based on the equipment information and the data. Each of the processing sections is a section corresponding to a transformer, or one of a plurality of divisions into which a section corresponding to a transformer is divided. Each of the phase groups is powered by the same phase of the second distribution line.

### Advantageous Effects of Invention

The phase group estimation device according to the present invention can achieve the effect of estimating which pole-mounted transformers belong to the same phase group without requiring measurement values of the voltage of the high-voltage distribution line.

### BRIEF DESCRIPTION OF DRAWINGS

FIG. 1 is a diagram illustrating an exemplary configuration of a smart meter system to which a phase group estimation device according to an embodiment is connected.

FIG. 2 is a diagram illustrating an exemplary functional configuration of the phase group estimation device.

FIG. 3 is a diagram illustrating an example of equipment information.

FIG. 4 is a diagram illustrating an exemplary configuration of a computing system for implementing the phase group estimation device.

FIG. 5 is a diagram illustrating an exemplary procedure for phase group estimation by the phase group estimation device.

FIG. 6 is a diagram illustrating an example of how pole-mounted transformers are connected to phases and an example of the voltage-time-history corresponding to each pole-mounted transformer.

FIG. 7 is a diagram illustrating an example of how pole-mounted transformers are connected to phases and another example of the voltage-time-history corresponding to each pole-mounted transformer.

FIG. 8 is a diagram illustrating an example of the group information obtained as the result of grouping by the phase group estimator.

FIG. 9 is a diagram illustrating an example of the group information in which information on a disconnection in the V-phase of the distribution line is reflected.

FIG. 10 is a flowchart illustrating an exemplary procedure for dealing with an event notification by the phase group estimation device.

FIG. 11 is a diagram illustrating an example of the relationship between different connection systems and disconnections in a distribution system.

FIG. 12 is a diagram illustrating an example of the result of estimation of the fault position according to the presence or absence of event notifications transmitted.

FIG. 13 is a diagram illustrating examples of the voltage time histories obtained when a disconnection occurs in the V-phase of the distribution line in the connection example illustrated in FIG. 6.

### DESCRIPTION OF EMBODIMENTS

Hereinafter, a phase group estimation device, a phase group estimation method, and a phase group estimation program according to an embodiment of the present invention will be described in detail based on the drawings. The present invention is not limited to the embodiment.

### Embodiment

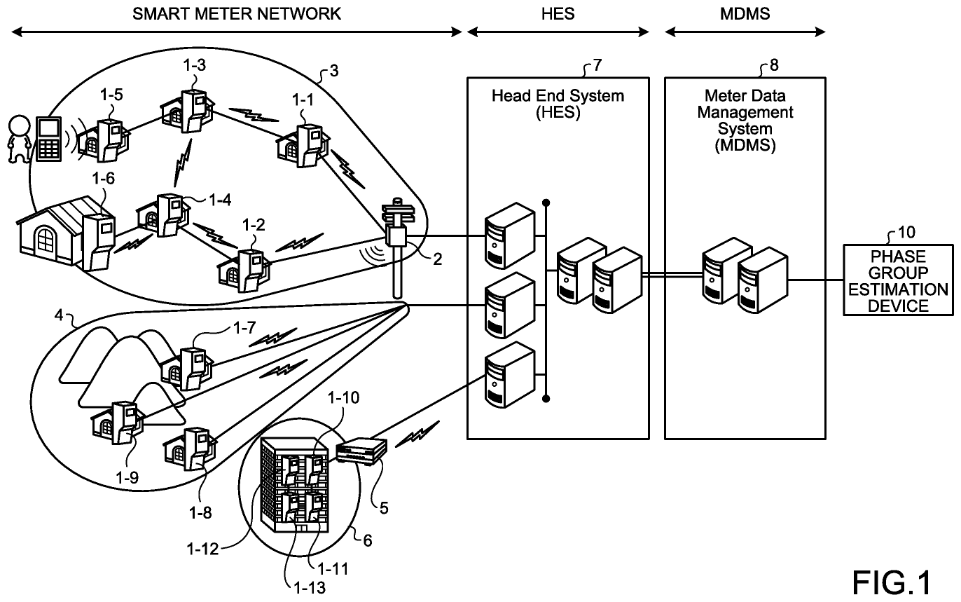

FIG. 1 is a diagram illustrating an exemplary configuration of a smart meter system to which a phase group estimation device according to an embodiment of the present invention is connected. The smart meter system according to the present embodiment includes a smart meter network, a head end system (HES) 7, and a meter data management system (MDMS) 8. As illustrated in FIG. 1, the phase group estimation device 10 of the present embodiment is communicably connected to the MDMS 8. Alternatively, the phase group estimation device 10 of the present embodiment can be configured as a piece of application software for the MDMS 8.

The smart meter network includes smart meters 1-1 to 1-13. Although thirteen smart meters are illustrated in FIG. 1, the number of smart meters is not limited to the example illustrated in FIG. 1. Any number of smart meters may be provided. Hereinafter, the smart meters 1-1 to 1-13 are referred to as the smart meter(s) 1 when they are not distinguished from one another.

The smart meters 1 are meter-reading devices for automatic meter reading, and are installed at premises of consumers such as homes, business offices, and factories. The smart meter 1 is an example of a measuring device capable of measuring the voltage of a first distribution line. The smart meter 1 can measure the amount of power used by loads at premises of the consumer, measure the voltage at the premises of the consumer, namely the voltage of the first distribution line, and transmit these measurement results. The smart meter 1 can also transmit an event notification for giving notice of an event such as a power failure, a power recovery, or a voltage drop. Hereinafter, measurement results and event notifications that are transmitted by the smart meter 1 are referred to as data that are transmitted by the smart meter 1 when the measurement results and the event notifications are not distinguished from each other. Details of data that are transmitted by the smart meter 1 will be described later.

Some consumers can have power generation facilities such as solar power generation facilities. Some smart meters 1 may be capable of measuring the amount of power generated by the power generation facilities at the premises of the consumer.

The smart meter network includes a multi-hop network 3, a mobile network 4, a power line communication (PLC) network 6, and the like. The smart meter network does not necessarily include all of the multi-hop network 3, the mobile network 4, and the PLC network 6 as illustrated in the example of FIG. 1. The smart meter network only needs to include one of the multi-hop network 3, the mobile network 4, and the PLC network 6. Furthermore, the smart meter network may include networks other than the multi-hop network 3, the mobile network 4, and the PLC network 6.

The multi-hop network 3 includes the smart meters 1-1 to 1-6 and a concentrator 2. The smart meters 1-1 to 1-6 transmit measurement results such as power usage and voltage and event notifications to the concentrator 2 serving as a master station. In addition, the MDMS 8 or the HES 7 can transmit a request message to each of the smart meters 1-1 to 1-6 via the concentrator 2, and each of the smart meters 1-1 to 1-6 can return the measurement result. The concentrator 2 and the smart meters 1-1 to 1-6 communicate with one another using a wireless multi-hop method.

The mobile network 4 includes the smart meters 1-7 to 1-9. The mobile network 4 is a network in which the smart meters 1-7 to 1-9 directly communicate with a base station (not illustrated). The smart meters 1-7 to 1-9 transmit measurement results such as power usage and voltage and event notifications to the base station. In addition, the MDMS 8 or the HES 7 can transmit a request message to each of the smart meters 1-7 to 1-9 via the base station, and each of the smart meters 1-7 to 1-9 can return the measurement result.

The PLC network 6 includes the smart meters 1-10 to 1-13 and a PLC concentrator 5. The PLC concentrator 5 and the smart meters 1-10 to 1-13 communicate with each other using a PLC method, i.e. communication via power lines. The smart meters 1-10 to 1-13 transmit measurement results such as power usage and voltage and event notifications to the PLC concentrator 5 serving as a master station. In addition, the MDMS 8 or the HES 7 can transmit a request message to each of the smart meters 1-10 to 1-13 via the PLC concentrator 5, and each of the smart meters 1-10 to 1-13 can return the measurement result.

The multi-hop network 3, the mobile network 4, and the PLC network 6 are connected to the HES 7. The HES 7 collects measurement results and event notifications from the smart meters 1 via the aggregate station of each network, namely the concentrator 2, the base station, and the PLC concentrator 5. The HES 7 also performs communication management of each network, request message management, and the like. The HES 7 collects measurement results and event notifications from each aggregate station, and transmits the collected measurement results and event notifications to the MDMS 8. The HES 7 includes, for example, one or more server devices.

The MDMS 8 manages the measurement results and event notifications received from the HES 7. The MDMS 8 includes, for example, one or more server devices.

The phase group estimation device 10 is communicably connected to the MDMS 8. In the examples described below, the phase group estimation device 10 is connected to the MDMS 8. Alternatively, the phase group estimation device 10 may be provided in the MDMS 8. Specifically, the phase group estimation device 10 may be implemented by a server device that constitutes the MDMS 8.

Here, data that are transmitted by the smart meter 1 will be described. Generally, the smart meter 1 periodically transmits the results of measurement of power usage. The contents of measurement results and the interval between periodic transmissions of measurement results may be set in advance, or the MDMS 8 may notify the smart meter 1 of the contents and the interval via the HES 7 and the aggregate station. The smart meter 1 voluntarily transmits measurement results according to the settings or notifications. Measurement results transmitted voluntarily include the results of measurement of power usage. Measurement results transmitted voluntarily may further include the results of measurement of voltage. The MDMS 8 can also individually instruct a specific smart meter 1 to transmit the result of measurement of voltage via the HES 7 and the aggregate station to acquire the measurement result from the smart meter 1. The voltage transmitted from the smart meter 1 may be an instantaneous value or the average of the values during a certain period. In the examples described below, the measurement results the smart meter 1 voluntarily transmits include the results of measurement of voltage.

Upon detecting an event such as a power failure or a voltage drop, the smart meter 1 transmits an event notification for giving notice of the event. Generally, the smart meter 1 is powered by electricity supplied by the first distribution line. In a case where the smart meter 1 has a function of giving notice of a power failure as an event, the smart meter 1 includes a device such as a battery that supplies power for a certain period. In this case, the smart meter 1 is normally powered by electricity supplied by the first distribution line, and in the event of a power failure, operates using an internal battery to transmit a power failure event notification. In a case where the smart meter 1 has a function of giving notice of a voltage drop as an event, the smart meter 1 transmits a voltage drop event notification in response to detecting a voltage less than a threshold.

Next, the phase group estimation device 10 will be described. In the present embodiment, the phase group estimation device 10 divides pole-mounted transformers into phase groups based on the voltages measured by the smart meters 1. That is, the phase group estimation device 10 estimates the phase to which each pole-mounted transformer is connected. In general, a multi-phase alternating current distribution system is not managed in terms of to which phase of the distribution line each pole-mounted transformer is connected. It is desirable to grasp which phase of the distribution line each pole-mounted transformer is connected to, for example, so as to grasp the extent of the influence of a disconnection in the distribution line. In particular, in the case of a three-phase three-wire system, even when a disconnection occurs in some phase of the distribution line, the voltage at the corresponding pole-mounted transformer may not become zero due to detouring from another phase, which makes it difficult to grasp the influence of the disconnection. In the present embodiment, the phase group estimation device 10 divides pole-mounted transformers into phase groups based on the voltages measured by the smart meters 1 without requiring measurement values from the high-voltage distribution line. Hereinafter, the configuration and operation of the phase group estimation device 10 will be described.

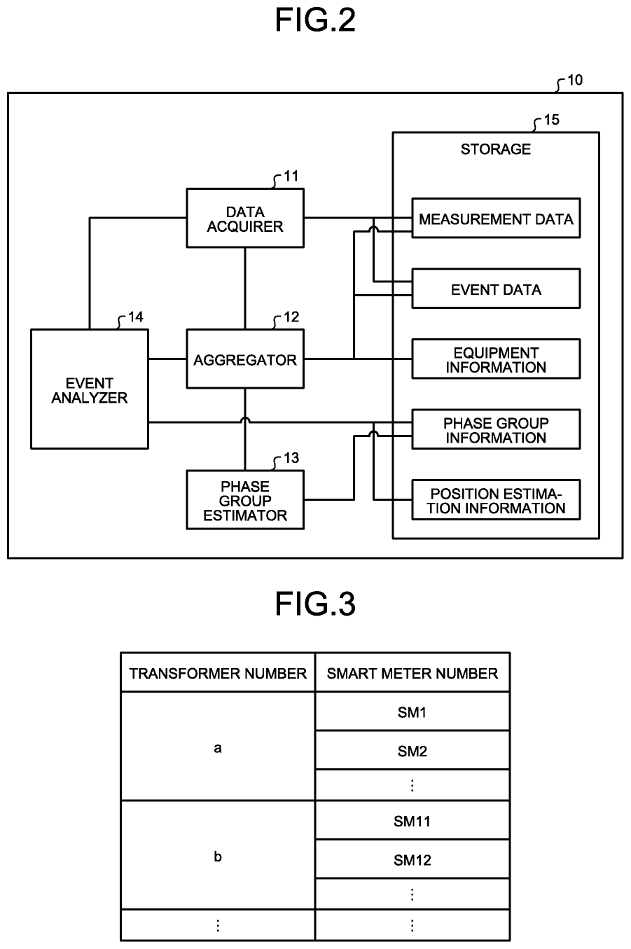

FIG. 2 is a diagram illustrating an exemplary functional configuration of the phase group estimation device 10. As illustrated in FIG. 2, the phase group estimation device 10 includes a data acquirer 11, an aggregator 12, a phase group estimator 13, an event analysis unit 14, and a storage 15.

The storage 15 can store measurement data, event data, equipment information, phase group information, and position estimation information. The measurement data are the voltages measured by the smart meters 1, but may include usage. The event data are information indicating the event contained in an event notification from the smart meter 1.

The equipment information is stored in advance in the storage 15 of the phase group estimation device 10 or received from an external system. The equipment information is information indicating the configuration of each piece of equipment in a distribution line. The equipment information includes information indicating the correspondence between pole-mounted transformers and the smart meters 1. Specifically, the equipment information includes information indicating the correspondence between measuring devices and pole-mounted transformers, i.e. transformers connected to the first distribution line corresponding to the measuring devices. A pole-mounted transformer is an example of an instrument connected to the first distribution line and connected to the second distribution line. In a case where an instrument connected to the first distribution line and connected to the second distribution line is a pole-mounted transformer, the first distribution line is a low-voltage distribution line, and the second distribution line is a high-voltage distribution line. A pole-mounted transformer is a transformer that converts the voltage in the high-voltage distribution line to the voltage in the low-voltage distribution line. The loads and power generation facilities at each premises of the consumer are connected to the low-voltage distribution line connected to a pole-mounted transformer. The smart meter 1 measures the amount of power used by loads at each premises of the consumer, the voltage of the low-voltage distribution line, and the like. Therefore, each of the smart meters 1 is associated with a single pole-mounted transformer.

FIG. 3 is a diagram illustrating an example of equipment information. In FIG. 3, information indicating the correspondence between pole-mounted transformers and the smart meters 1 is illustrated as an example of equipment information. Other types of information may be included in the equipment information. In the example illustrated in FIG. 3, the equipment information includes transformer numbers, i.e. an example of information for identifying pole-mounted transformers, and smart meter numbers, i.e. an example of information for identifying the smart meters 1. The equipment information illustrated in FIG. 3 indicates, for example, that the low-voltage distribution line connected to the pole-mounted transformer with transformer number “a” is associated with the smart meters 1 with smart meter numbers SM1, SM2, etc.

The phase group information is information indicating the result of estimation in the phase group estimation process described later. The position estimation information is information indicating the result of estimation in the position estimation process described later, that is, the result of estimation of the position where a fault such as a disconnection has occurred.

The data acquirer 11 acquires, from the MDMS 8, data transmitted by the smart meter 1, that is, data transmitted from the smart meter 1, and stores the acquired data in the storage 15 as measurement data. The data acquirer 11 may acquire all the data transmitted by the smart meter 1 and received by the MDMS 8 or may acquire only the data that are used for the processes described later.

The aggregator 12 aggregates the measurement data stored in the storage 15. Specifically, using the measurement data and the equipment information stored in the storage 15, the aggregator 12 calculates the voltage-time-history of each processing section. A processing section is the smallest unit for calculating the voltage-time-history in the phase group estimation process described later. A processing section is a section represented by one piece of measurement data in a high-voltage distribution line that is a phase group estimation target, and can also be described as a unit section for measurement data acquisition. A processing section is, for example, an area corresponding to one pole-mounted transformer, that is, the section between one pole-mounted transformer and the load-side end of the low-voltage distribution line connected to the pole-mounted transformer. Basically, a processing section is a unit connected to the same phase like a section connected to a pole-mounted transformer. The following examples are based on the assumption that the area corresponding to a pole-mounted transformer is the smallest unit of section connected to the same phase. However, there are situations in which the smallest unit of section connected to the same phase is not the area corresponding to a pole-mounted transformer. For example, high-voltage power may be supplied from a high-voltage distribution line to homes, business offices, and the like without passing through a transformer. Even in such a case, a unit connected to the same phase can be considered a processing section. In this case, the voltage that is measured by the smart meter 1, or a measuring device, is the voltage of the high-voltage distribution line. Moreover, an instrument connected to the first distribution line and connected to the second distribution line is not limited to a transformer. In the following examples, each of the processing sections is the area corresponding to one pole-mounted transformer. However, a processing section may be wider or narrower than the area corresponding to one processing section as long as it is determined according to the configuration of the distribution system.

Using the voltage-time-history of each processing section calculated by the aggregator 12, the phase group estimator 13 divides the processing sections into a plurality of phase groups. Based on this result, the phase group estimator 13 estimates the phase group to which each pole-mounted transformer belongs. Specifically, based on the equipment information and the data transmitted from the smart meter 1, the phase group estimator 13 classifies the processing sections into phase groups, each including the processing sections powered by the same phase of the second distribution line.

When an event notification is transmitted from the smart meter 1, the event analysis unit 14 divides the processing sections into a plurality of phase groups based on the event notification. Specifically, based on the equipment information and the event notification, which is the data transmitted from the smart meter 1, the event analysis unit 14 classifies the processing sections into phase groups, each including the processing sections powered by the same phase of the distribution line. The event analysis unit 14 also estimates the position where a fault such as a disconnection has occurred based on the event notification, and stores the estimated position in the storage 15 as position estimation information.

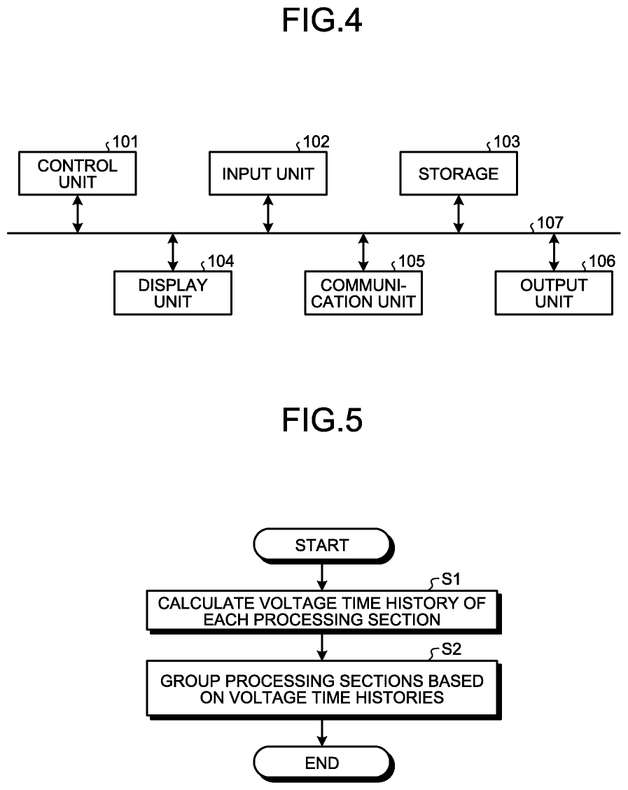

The phase group estimation device 10 is specifically a computing system, that is, a computer. A phase group estimation program is executed on the computing system, whereby the computing system functions as the phase group estimation device 10. FIG. 4 is a diagram illustrating an exemplary configuration of a computing system for implementing the phase group estimation device 10 of the present embodiment. As illustrated in FIG. 4, the computing system includes a control unit 101, an input unit 102, a storage 103, a display unit 104, a communication unit 105, and an output unit 106, which are coupled to one another via a system bus 107.

In FIG. 4, the control unit 101 is, for example, a central processing unit (CPU) or the like. The control unit 101 executes the phase group estimation program, i.e. the program containing the processes in the phase group estimation device 10 of the present embodiment. The input unit 102 includes, for example, a keyboard, a mouse, and the like, and is used by the user of the computing system to input various types of information. The storage 103 includes various types of memories such as a random access memory (RAM) and a read only memory (ROM) and a storage device such as a hard disk. The storage 103 stores, for example, programs to be executed by the control unit 101 and necessary data obtained during processing. The storage 103 is also used as a temporary storage area for programs. The display unit 104 includes a liquid crystal display (LCD) panel or the like, and displays various screens to the user of the computing system. The communication unit 105 performs communication processing. Note that FIG. 4 is an example, and the configuration of the computing system is not limited to the example of FIG. 4.

Here, an example of how the computing system operates until the phase group estimation program of the present embodiment becomes executable state is described. In the computing system having the above-mentioned configuration, for example, the phase group estimation program is installed on the storage 103 from a compact disc (CD)-ROM or digital versatile disc (DVD)-ROM which are set in a CD-ROM drive or DVD-ROM drive (not illustrated). Then, when the phase group estimation program is executed, the phase group estimation program read from the storage 103 is stored in a predetermined area of the storage 103. In this state, the control unit 101 executes the processes as the phase group estimation device 10 of the present embodiment in accordance with the program stored in the storage 103.

In the above description, the program containing the processes in the phase group estimation device 10 is provided using a CD-ROM or DVD-ROM as a recording medium. Alternatively, the program may be provided by a transmission medium such as the Internet via the communication unit 105 according to the configuration of the computing system, the capacity of the program, and the like.

The aggregator 12, the phase group estimator 13, and the event analysis unit 14 illustrated in FIG. 2 are implemented by the control unit 101 in FIG. 4. The storage 15 illustrated in FIG. 2 is a part of the storage 103 illustrated in FIG. 4. The data acquirer 11 illustrated in FIG. 2 is implemented by the communication unit 105 and the control unit 101 illustrated in FIG. 4.

The phase group estimation device 10 according to the present embodiment may be incorporated in the MDMS 8 as described above. In this case, the server device, namely the computing system that constitutes the MDMS 8, also functions as the computing system illustrated in FIG. 4.

Next, the operation of the phase group estimation device 10 of the present embodiment will be described. FIG. 5 is a diagram illustrating an exemplary procedure for phase group estimation by the phase group estimation device 10 of the present embodiment. As illustrated in FIG. 5, first, the aggregator 12 of the phase group estimation device 10 uses the measurement data and the equipment information stored in the storage 15 to calculate the voltage-time-history V (i, t) of each processing section (step S1).

In V (i, t), “i” is an integer of zero or more and is a number for identifying a processing section. In V (i, t), “t” is time. Note that “t” is, for example, an integer representing time. For example, t=0 can represent the period from time T₀ to time T₁=T₀+ΔT, and t=1 can represent the period from time T₁ to time T₂=T₀+2ΔT. In this manner, “t” can be an integer representing time as a function of a predetermined time ΔT. Here, ΔT can be, for example, the interval between collections of measurement results from the smart meter 1. However, ΔT is not limited to this. Note that a measurement result provided by the smart meter 1 includes additional information, in particular the measurement time and the number of the smart meter 1, and each measurement result is stored in the storage 15 as measurement data together with the measurement time and the number of the smart meter 1. The aggregator 12 calculates the voltage-time-history V (i, t) of each processing section based on the measurement times and measurement results of each smart meter 1 stored as measurement data in the storage 15.

A processing section explained here as an example is the section corresponding to one pole-mounted transformer. In general, a plurality of smart meters 1 are included in each processing section. The aggregator 12 selects, for example, the smart meter 1 representing each processing section from among the plurality of smart meters 1 in each processing section, and uses the measurement results of the smart meter 1 representing each processing section to calculate the voltage-time-history V (i, t). Alternatively, the aggregator 12 may calculate the voltage-time-history V (i, t) using the average of the measurement results of all the smart meters 1 in each processing section, or may calculate the voltage-time-history V (i, t) using the maximum value, minimum value, or intermediate value of the measurement results of the smart meters 1 in each processing section.

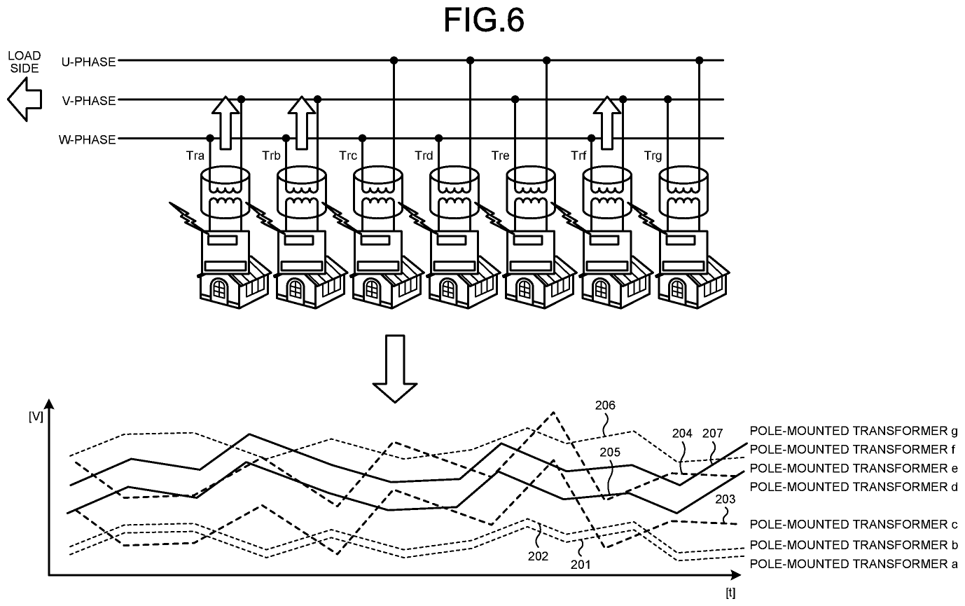

FIG. 6 is a diagram illustrating an example of how pole-mounted transformers are connected to phases and an example of the voltage-time-history V (i, t) corresponding to each pole-mounted transformer. The upper part of FIG. 6 schematically depicts an example of how the seven pole-mounted transformers with pole-mounted transformer numbers “a” to “g” are connected to phases. In FIG. 6, the pole-mounted transformers are abbreviated to “Tr”. For example, “Tra” indicates the pole-mounted transformer with transformer number “a”. Hereinafter, the pole-mounted transformers with transformer numbers “a” to “g” are referred to as pole-mounted transformers a to g, respectively. In the example illustrated in FIG. 6, pole-mounted transformers a to g are connected to a three-phase three-wire distribution line. Specifically, pole-mounted transformers a, b, and f are connected to the V- and W-phases of the three-phase three-wire distribution line, pole-mounted transformers c and d are connected to the W- and U-phases of the three-phase three-wire distribution line, and pole-mounted transformers e and g are connected to the U- and V-phases of the three-phase three-wire distribution line.

The lower part of FIG. 6 schematically depicts an example of the voltage-time-history V (i, t) calculated for each processing section by the aggregator 12 based on the connection example illustrated in the upper part of FIG. 6. In the example illustrated in FIG. 6, each processing section corresponds to one pole-mounted transformer. FIG. 6 depicts an example of the voltage-time-history V (i, t) of each pole-mounted transformer. For example, i=0 represents the processing section corresponding to pole-mounted transformer a, i=1 represents the processing section corresponding to pole-mounted transformer b, i=2 represents the processing section corresponding to pole-mounted transformer c, i=3 represents the processing section corresponding to pole-mounted transformer d, i=4 represents the processing section corresponding to pole-mounted transformer e, i=5 represents the processing section corresponding to pole-mounted transformer f, and i=6 represents the processing section corresponding to pole-mounted transformer g. In this case, the voltage-time-history V (0, t) is a profile 201 of the processing section corresponding to pole-mounted transformer a, the voltage-time-history V (1, t) is a profile 202 of the processing section corresponding to pole-mounted transformer b, and the voltage-time-history V (2, t) is a profile 203 of the processing section corresponding to pole-mounted transformer c. The voltage-time-history V (3, t) is a profile 204 of the processing section corresponding to pole-mounted transformer d, the voltage-time-history V (4, t) is a profile 205 of the processing section corresponding to pole-mounted transformer e, the voltage-time-history V (5, t) is a profile 206 of the processing section corresponding to pole-mounted transformer f, and the voltage-time-history V (6, t) is a profile 207 of the processing section corresponding to pole-mounted transformer g.

Here, the group connected to the U- and V-phases is referred to as phase group A, the group connected to the W- and U-phases is referred to as phase group B, and the group connected to the V- and W-phases is referred to as phase group C. As illustrated in FIG. 6, for example, the profiles 205 and 207 corresponding to pole-mounted transformers e and g that belong to phase group A show substantially similar temporal fluctuations.

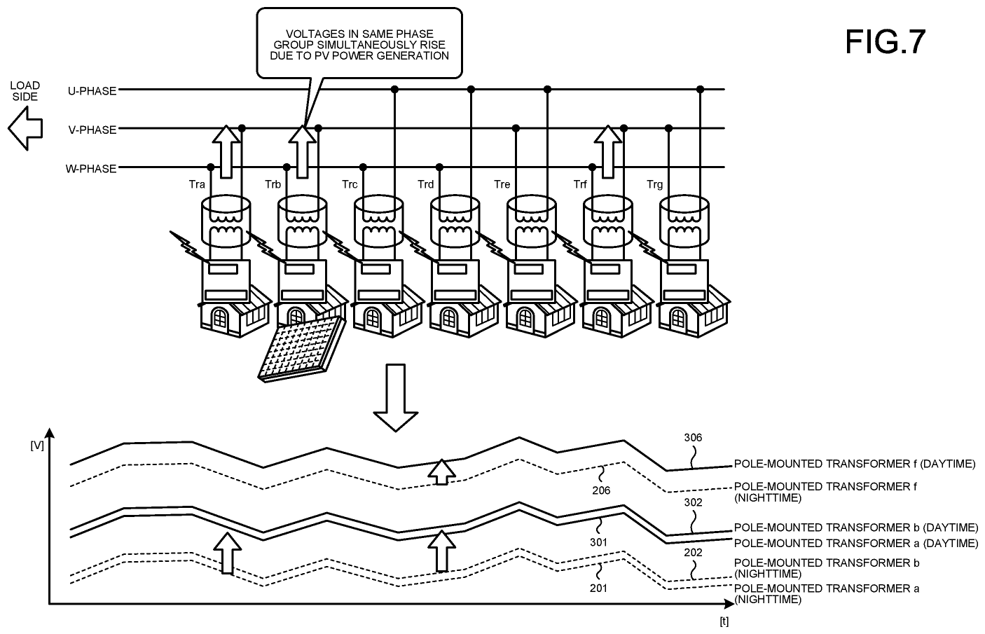

FIG. 7 is a diagram illustrating an example of how pole-mounted transformers are connected to phases and another example of the voltage-time-history V (i, t) corresponding to each pole-mounted transformer. In the example illustrated in FIG. 7, pole-mounted transformers a to g are connected to phases in the same manner as in the example illustrated in FIG. 6. The lower part of FIG. 7 depicts the daytime and nighttime voltage time histories V (i, t) of pole-mounted transformers a, b, and f that belong to phase group C. The profiles 201, 202, and 206 represent the daytime voltage time histories V (i, t) corresponding to pole-mounted transformers a, b, and f, respectively. Profiles 301, 302, and 306 represent the nighttime voltage time histories V (i, t) corresponding to pole-mounted transformers a, b, and f, respectively. The arrows in the lower part of FIG. 7 represent the rapid voltage rises caused by the solar power generation facility installed in the processing section corresponding to pole-mounted transformer b. Thus, the processing sections that simultaneously experience rapid voltage rises are likely to belong to the same phase group.

As illustrated in FIG. 7, since power usage and the amount of power generation vary according to the time of day such as daytime and nighttime, the voltage-time-history can vary according to the time of day. Similarly, the voltage-time-history may vary according to the day of the week and the weather. Therefore, the measured voltages are divided according to the time of day, the day of the week, the weather, etc., and the processing sections in each of the divisions are grouped. In this manner, the influence of phase groups can be separated from the influence of other factors such as the time of day, enabling accurate grouping of the processing sections.

As illustrated in FIGS. 6 and 7, the profiles of the processing sections corresponding to the pole-mounted transformers connected to the same two phases show substantially similar temporal fluctuations. Thus, in the present embodiment, the fact that temporal voltage fluctuations in the same phase group are substantially similar is used for grouping the processing sections.

Referring back to FIG. 5, after step S1, the phase group estimator 13 groups the processing sections based on the voltage time histories (step S2). The phase group estimator 13 stores the grouping result as group information in the storage 15, and ends the process. As described with reference to FIG. 6, temporal voltage fluctuations in the same phase group are substantially similar. Therefore, the processing sections can be grouped using, for example, correlation processing, pattern matching processing, etc. That is, the phase group estimator 13 classifies the processing sections into phase groups based on temporal voltage fluctuations. However, at this point, even though the processing sections can be grouped, the correspondence between the groups and the phases may not always be determined.

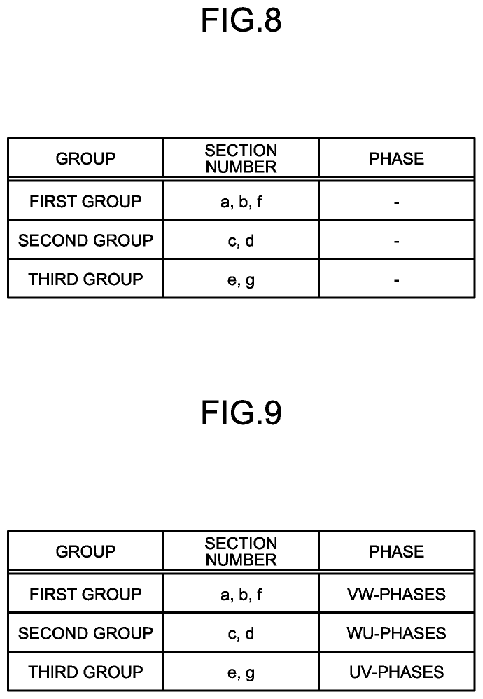

FIG. 8 is a diagram illustrating an example of the group information obtained as the result of grouping by the phase group estimator 13. As illustrated in FIG. 8, the group information includes information for identifying groups and information indicating the phases corresponding to section numbers. The section numbers are information for identifying processing sections. In the example illustrated in FIG. 8, the information for identifying groups is represented by group names such as the first group, the second group, and the third group. However, the information for identifying groups is not limited to this example. In the example illustrated in FIG. 8, the section numbers are represented by pole-mounted transformer numbers based on the connection example illustrated in FIG. 6. However, the section numbers are not limited to this example. In the example illustrated in FIG. 8, the correspondence between the groups and the phases is unknown, and the information indicating the corresponding phases is unknown.

The processing sections can be grouped through the above processing. In the example described above, the phase grouping process is performed once. However, a typical distribution system includes many pole-mounted transformers. If this group process is performed by using the measurement data corresponding to all the pole-mounted transformers at one time, a mixture of various errors can hinder precise grouping. For this reason, it is desirable that the process be divided into multiple stages as described below.

For example, suppose 100 pole-mounted transformers #1 to #100 exist in a distribution system. In this case, as the first stage of the process, the processing sections, i.e. units for measurement data acquisition in the distribution system, are divided into a plurality of processing groups, and the above-mentioned phase grouping process is performed on each of the processing groups. For example, the pole-mounted transformers are grouped in the following manner: the processing sections corresponding to pole-mounted transformers #1 to #5 are classified as the first processing group, the processing sections corresponding to pole-mounted transformers #5 to #9 are classified as the second processing group, and the processing sections corresponding to pole-mounted transformers #9 to #13 are classified as the third processing group. The processing sections corresponding to pole-mounted transformer #14 and the subsequent pole-mounted transformers are similarly divided into processing groups. It is desirable that a pole-mounted transformer in one processing group be also included in an adjacent processing group, in other words, sections of the corresponding high-voltage distribution line be overlapped with each other. However, the method of grouping into processing groups is not limited to this example, and the pole-mounted transformers may be grouped without any overlap. In the manner described with reference to FIG. 5, the processing sections in each processing group are divided into phase groups. Once this grouping is completed, as the second stage of the process, the processing sections are divided into higher-level groups, i.e. groups wider than the first-stage processing groups. In the second stage of the process, for each of the higher-level groups, the processing sections determined to be in the same phase group in the first stage of the process are collectively regarded as one processing section, and the processing sections in each processing group are divided into phase groups in the manner described with reference to FIG. 5.

To sum up, the phase group estimator 13 divides the processing sections into processing groups including a plurality of processing sections, and classifies the processing sections in each processing group into phase groups. Then, the phase group estimator 13 divides the processing sections into higher-level processing groups including more processing sections than the processing groups, and uses the result of classification of each processing group into phase groups to classify the processing sections in each higher-level processing group into phase groups. In a similar manner, the third and subsequent stages of the process may be performed.

The phase group estimation process of the present embodiment may be performed at any timing. For example, the phase group estimation process is performed when the operation of the phase group estimation device 10 is started, and performed again when the equipment information is changed, for example. The phase group estimation process is also performed when the configuration of the distribution system is changed. Furthermore, in the absence of any change in the equipment information and the distribution system configuration, there is still a possibility that the connections between the pole-mounted transformers and the phases may be changed for some reason. Therefore, the process illustrated in FIG. 5 may be performed periodically, e.g. once in several years.

The correspondence between the groups defined by the phase group estimator 13 and the phases can be grasped, for example, when a worker directly checks the connection of the pole-mounted transformers corresponding to each group. In this case, the worker only needs to check the connection of one of the pole-mounted transformers that belong to the same group. Alternatively, after a disconnection occurs in some phase of the distribution line, the disconnected phase and part of the distribution line are identified. For example, the disconnected phase of the distribution line is identified from the result of measurement by a sensor-equipped switch in the high-voltage system. For example, suppose a disconnection occurs in the V-phase of the distribution line in the connection example illustrated in FIG. 6. In this case, the voltage in the processing sections corresponding to the pole-mounted transformers connected to the V-phase decreases. However, the voltage in the processing sections corresponding to the pole-mounted transformers that are not connected to the V-phase is not affected. For this reason, after the disconnected phase is identified, it is possible to distinguish between the groups connected to the V-phase and the group that is not connected to the V-phase according to whether the voltage has decreased. However, while it is determined that the group that is not connected to the V-phase is the group connected to the W- and U-phases described above, it is not determined which of the remaining two groups is the group connected to the U- and V-phases and which is the group connected to the V- and W-phases. After repeated disconnections in various phases, the connections between the groups and the phases are identified.

The equipment information is changed, for example, when a new smart meter 1 is installed, that is, a facility of a new consumer is connected to the low-voltage distribution line, or when an existing smart meter 1 is removed, that is, a facility of a consumer is removed from the low-voltage distribution line. Therefore, if the equipment information is changed, the phase group estimator 13 determines whether the voltage in each processing section has changed due to the change in the equipment information, and can estimate the processing sections that have undergone voltage changes to be in the same phase group. That is, when the equipment information is changed, the phase group estimator 13 may classify the processing sections into phase groups using the data obtained before the change in the equipment information and the data obtained after the change in the equipment information. In this case, if a power failure occurs in an entire area due to a large-scale fault in the distribution system, wiring work, etc., a plurality of phase groups undergo the same change. In such a case, the corresponding processing sections are excluded from the phase group determination process for the period of the power failure. In other words, when a power failure is expected to happen within a certain area, the phase group estimator 13 excludes the certain area from the classification into phase groups for the expected period of the power failure.

FIG. 9 is a diagram illustrating an example of the group information including the determined phase groups. As described above, at the time that a disconnection occurs in the V-phase of the distribution line, it cannot be determined which of the first and third groups is the group connected to the U- and V-phases and which is the group connected to the V- and W-phases. By combining various types of information, the identity of each group is determined. In FIG. 9, the group connected to the U-phase and V-phase is represented by UV-phases, the group connected to the V-phase and W-phase is represented by VW-phases, and the group connected to the W-phase and U-phase is represented by WU-phases.

The above-described examples are based on the premise that the smart meters 1 periodically transmit voltages. However, in a case where the smart meters 1 do not periodically transmit voltages, the phase group estimation device 10 can individually designate the smart meters 1 via the MDMS 8 to collect voltages, thereby performing the above-mentioned process. For example, the phase group estimation device 10 designates one or more smart meters 1 in each processing section to collect voltages. As described above, the process illustrated in FIG. 5 need not necessarily be performed frequently, and the collection of voltages from the individual smart meters 1 may be performed at least when the process illustrated in FIG. 5 is performed. Therefore, the collection of voltages from the individual smart meters 1 hardly affects the communication capacity.

After the phase group to which each processing section belongs is estimated in the process described above, the phase group estimation device 10 notifies an operator of the result, for example, by displaying the result on the display unit 104. Consequently, in the event of a disconnection in the distribution line, the operator can grasp the extent of the influence of the disconnection. The operator can also understand which phase each pole-mounted transformer is connected to. Therefore, when a new pole-mounted transformer is installed, the number of pole-mounted transformers connected to each phase can be equalized, or conversely, the number of connections to a particular phase can be increased.

There may be a pole-mounted transformer to which phases the pole-mounted transformer is connected has been already known. In such a case, the phase group estimator 13 reflects the known information in the phase group information. Specifically, the phase group estimator 13 reflects connected phase information about the processing section that has known connections to phases. This enables more appropriate phase group estimation.

Next, the process of dealing with an event notification by the phase group estimation device 10 of the present embodiment will be described. As described above, the smart meter 1 transmits an event notification upon detecting an event such as a power failure or a voltage drop. In response to receiving the event notification via the MDMS 8, the data acquirer 11 of the phase group estimation device 10 notifies the event analysis unit 14 that the event notification has been received. The event notification contains the smart meter number and the time that the smart meter 1 detected the event. The data acquirer 11 stores the received event notification as event data in the storage 15.

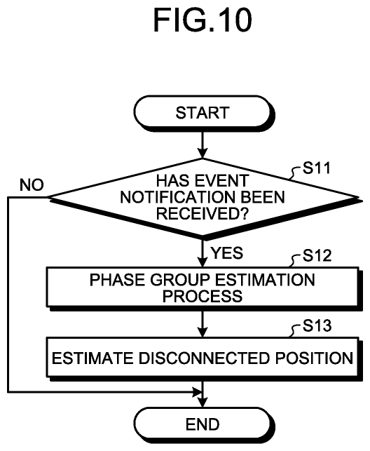

FIG. 10 is a flowchart illustrating an exemplary procedure for dealing with an event notification by the phase group estimation device 10 of the present embodiment. First, the event analysis unit 14 determines whether an event notification has been received (step S11). If the event analysis unit 14 determines that an event notification has been received (step S11: Yes), the event analysis unit 14 performs an event-notification-based phase group estimation process (step S12). In this case, the event analysis unit 14 serves as a phase group estimator that classifies the processing sections into phase groups, each including the processing sections powered by the same phase of the distribution line, based on the equipment information and the event notification, which is the data transmitted from the smart meter 1.

The event-notification-based phase group estimation process is the process of putting, into the same group, the processing sections corresponding to the smart meters 1 which have transmitted event notifications of the same content simultaneously or within a predetermined period of time. The event-notification-based phase group estimation process is the same as the voltage-based phase group estimation process except for using the presence or absence of event notifications transmitted instead of voltage fluctuations. In any case, the phase group estimation device 10 puts, into the same group, the processing sections including the smart meters 1 that transmit the same or similar data.

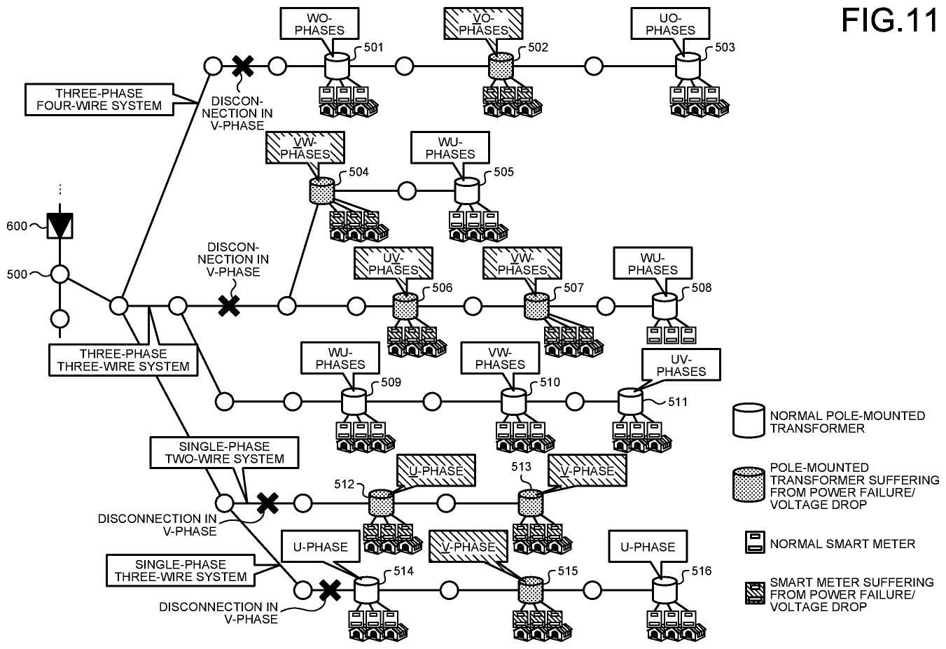

FIG. 11 is a diagram illustrating an example of the relationship between different connection systems and disconnections in a distribution system. As illustrated in FIG. 11, the pole-mounted transformers are connected to distribution lines that branch from the high-voltage distribution line wired to a high-voltage pole 500 using various connection systems such as a single-phase three-wire system, a single-phase two-wire system, a three-phase three-wire system, and a three-phase four-wire system. A sensor-equipped section switch 600 measures the voltage of the high-voltage distribution line. In the examples of FIGS. 6 and 7, phase groups are estimated in a three-phase three-wire system. However, the phase group estimation method of the present embodiment can be applied to other connection systems as well as a three-phase three-wire system. In the example of FIG. 11, various connection systems coexist. However, the phase group estimation device 10 of the present embodiment is expected to perform estimation typically in an area with a single connection system. In a case where the phase group estimation device 10 of the present embodiment performs estimation in an area with a plurality of connection systems, the phase group estimation device 10 determines phase groups for each of the connection systems.

As illustrated in FIG. 11, among pole-mounted transformers 501 to 516, the pole-mounted transformers 501 to 503 are connected using a three-phase four-wire system, the pole-mounted transformers 504 to 511 are connected using a three-phase three-wire system, the pole-mounted transformers 512 and 513 are connected using a single-phase two-wire system, and the pole-mounted transformers 514 to 516 are connected using a single-phase three-wire system. Above the pole-mounted transformers 501 to 516, the connected phases are indicated. In the example illustrated in FIG. 11, a disconnection occurs in the V-phase of the distribution line on the upstream side of the pole-mounted transformer 501, a disconnection occurs in the V-phase of the distribution line on the upstream side of the pole-mounted transformers 504 and 506, a disconnection occurs in the V-phase of the distribution line on the upstream side of the pole-mounted transformer 512, and a disconnection occurs in the V-phase of the distribution line on the upstream side of the pole-mounted transformer 514. In FIG. 11, in each connection system, hatchings are used to indicate pole-mounted transformers that are affected, that is, suffer from a power failure or voltage drop, by a disconnection in the V-phase. Similarly, hatchings are used to indicate smart meters 1 that are affected, that is, suffer from a power failure or voltage drop, by a disconnection in the V-phase.

As described above, the fact that whether a pole-mounted transformer is affected by a disconnection in some phase depends on the phase the pole-mounted transformer is connected to can be used for grouping the processing sections. For example, suppose a disconnection occurs in the V-phase of the distribution line in a three-phase three-wire system. In this case, the disconnection affects the pole-mounted transformers located downstream of the disconnected part and connected to the UV-phases and the pole-mounted transformers located downstream of the disconnected part and connected to the VW-phases. Therefore, the smart meters 1 corresponding to these pole-mounted transformers transmit event notifications, whereas the other smart meters 1 do not transmit event notifications. Therefore, the processing sections can be grouped according to the presence or absence of event notifications transmitted at the same time or within a predetermined period of time.

Referring back to FIG. 10, after step S12, the event analysis unit 14 estimates the disconnected or fault position based on the event notifications (step S13). The event analysis unit 14 functions as a position estimator that estimates the location of the disconnection based on the event notifications. The event analysis unit 14 stores the result of estimation of the disconnected position as position information in the storage 15, and ends the process. The disconnected or fault position is estimated to be on the boundary between the processing sections that have transmitted event notifications and the processing sections that have not transmitted event notifications among the processing sections that belong to the same group. In this case, using the measurement result of the voltage of each processing section, the event analysis unit 14 can understand whether the voltage has dropped in each processing section, enabling more accurate estimation of the fault position.

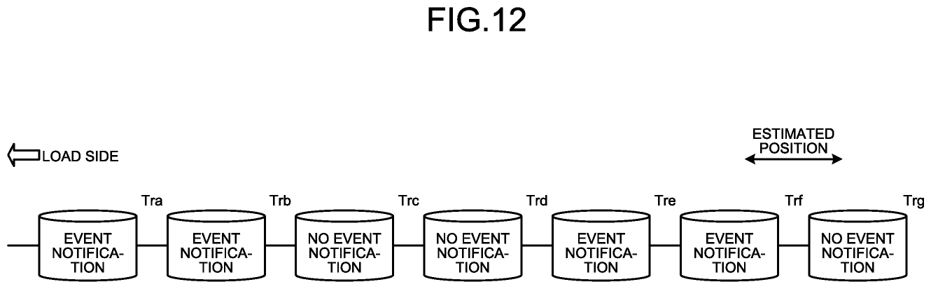

FIG. 12 is a diagram illustrating an example of the result of estimation of the fault position according to the presence or absence of event notifications transmitted. The example illustrated in FIG. 12 is based on the premise that the phase group to which each processing section belongs has been determined based on the connection example illustrated in FIG. 6. As illustrated in FIG. 12, if pole-mounted transformer f has transmitted an event notification and pole-mounted transformer g has not transmitted an event notification, the fault position can be estimated to be between pole-mounted transformer f and pole-mounted transformer g.

In a case where the smart meter 1 does not periodically transmit voltages, the phase group estimation device 10 may collect voltages from the smart meter 1 in response to receiving an event notification from the smart meter 1.

As described above, the phase group estimation device 10 can classify the processing sections into phase groups based on the time of occurrence of an event using event notifications. However, the event-notification-based phase group estimation cannot be implemented unless an event occurs. Thus, the above-mentioned voltage-based phase group estimation and the event-notification-based estimation can be used together for more precise phase group determination.

In a case where the smart meter 1 is configured not to transmit a power failure notification but to transmit a voltage drop notification as an event notification, a voltage drop can cause a power failure and prevent the smart meter 1 from transmitting a voltage drop notification. The smart meter 1 configured to transmit a power failure notification includes a battery, whereas the smart meter 1 configured to transmit a voltage drop notification generally does not include a battery. For this reason, when the voltage becomes almost zero, the smart meter 1 loses power and cannot transmit a voltage drop notification.

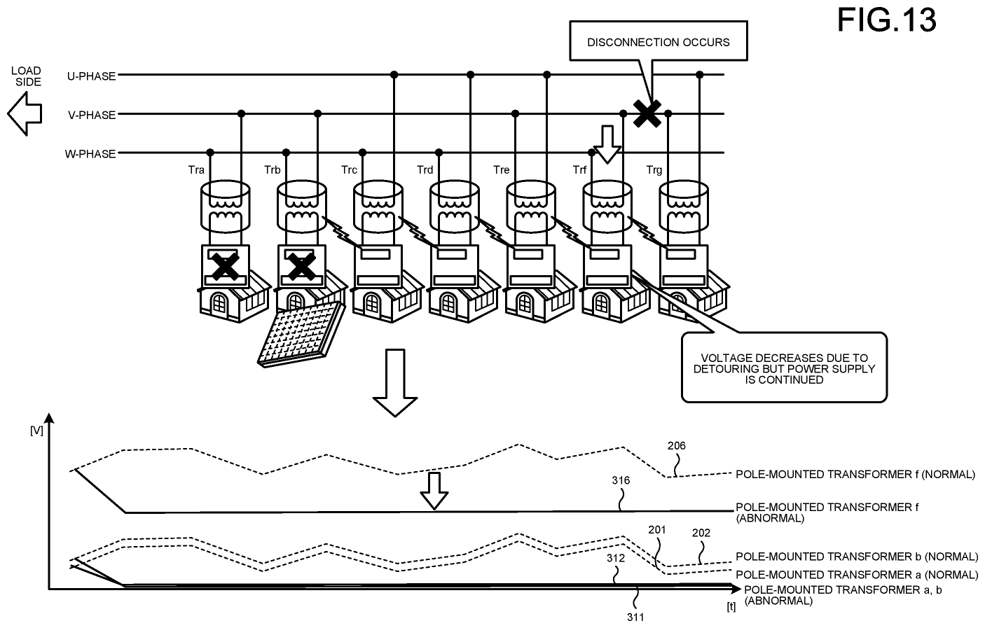

FIG. 13 is a diagram illustrating examples of the voltage time histories V (i, t) obtained when a disconnection occurs in the V-phase of the distribution line in the connection example illustrated in FIG. 6. FIG. 13 illustrates an example in which a disconnection occurs in the V-phase of the distribution line between pole-mounted transformer g and pole-mounted transformer f. In this case, as illustrated in the lower part of FIG. 13, the normal profiles 201, 202, and 206 of pole-mounted transformers a, b, and f that belong to phase group C are the same as those in the example of FIG. 6. Profiles 311, 312, and 316 represent the voltage time histories V (i, t) of pole-mounted transformers a, b, and f that belong to phase group C obtained when a disconnection in the V-phase occurs. In the processing section corresponding to pole-mounted transformer f, the voltage is not zero due to voltage detouring. Therefore, the smart meter 1 of the processing section corresponding to pole-mounted transformer f can transmit a voltage drop notification. Voltage detouring is a phenomenon in which the voltage of a pole-mounted transformer connected to the disconnected phase does not become zero because currents flowing through other pole-mounted transformers connected to the normal phases of the distribution line detour into the pole-mounted transformer connected to the disconnected phase. In the processing sections corresponding to pole-mounted transformers a and b, the voltage becomes zero. Therefore, the smart meters 1 of the processing sections corresponding to pole-mounted transformers a and b cannot transmit voltage drop notifications.

In the case of the example illustrated in FIG. 13, it is difficult to estimate phase groups only with voltage drop notifications. Therefore, when the data acquirer 11 of the phase group estimation device 10 receives a voltage drop notification, the data acquirer 11 individually requests the smart meters 1 to acquire voltages, thereby collecting the results of measurement of voltage and estimating phase groups based on the above-mentioned voltage-time-history using the results of measurement of voltage. In this manner, phase groups can be estimated using a combination of voltage and voltage drop notification. In the case of estimating the location of a disconnection using the estimated phase groups, voltages are collected from the smart meters 1 that belong to the same phase group and are located around the smart meter 1 that has transmitted a voltage drop notification, whereby the location of the voltage drop can be estimated.

In the examples described in the present embodiment, a transformer that converts the voltage in the high-voltage distribution line to the voltage in the low-voltage distribution line is a pole-mounted transformer installed on a utility pole. Alternatively, some or all of the transformers that convert the voltage in the high-voltage distribution line to the voltage in the low-voltage distribution line may be installed somewhere other than on utility poles. In this case, phase group estimation can be performed on a transformer-by-transformer basis in the same manner as above.

In the above-described examples, the smart meter 1 is used as an example of a measuring device that measures the voltage of the low-voltage distribution line and transmits the measurement result. Instead of the smart meter 1, a measuring device that measures the voltage of the low-voltage distribution line and transmits the measurement result may be a measuring device other than the smart meter 1. The communication network that a measuring device other than the smart meter 1 uses when transmitting the measurement result may be the same as or different from the communication network that the smart meter 1 uses. The phase group estimation device 10 may perform phase group estimation using both the result of measurement of voltage provided by the smart meter 1 and the result of measurement of voltage provided by a measuring device other than the smart meter 1. A measuring device other than the smart meter 1 may have the above-mentioned function of transmitting event notifications. The smart meter 1 and a measuring device other than the smart meters 1 may transmit currents or the like in addition to voltages. The phase group estimation device 10 may perform phase group estimation using currents or the like in addition to voltages.

In the above-mentioned examples, the first distribution line is a low-voltage distribution line. As described above, however, the first distribution line may be a high-voltage distribution line, and the phase group estimation method of the present embodiment can also be applied to a case where the smart meter 1 is connected to a high-voltage distribution line. In this case, as described above, a measuring device other than the smart meter 1 may measure the voltage of the high-voltage distribution line in the same manner as the smart meter 1. This measuring device may have the function of transmitting event notifications. In this case, as described above, the smart meter 1 and a measuring device other than the smart meter 1 may transmit currents or the like in addition to voltages.

As described above, the phase group estimation device 10 according to the present embodiment estimates the phase group to which each processing section belongs based on the data transmitted from the smart meters 1. Therefore, groups can be estimated without the need to measure the voltage of the high-voltage system. Consequently, the extent of the influence of a disconnection can be estimated. In addition, the system need not cooperate with a system that measures the voltage of the high-voltage system and thus can have a simplified configuration. Among the data transmitted from the smart meters 1, the device only needs to store the data necessary for processing. Therefore, the device can be created inexpensively. Furthermore, the location of a disconnection can be estimated.

As described above, one smart meter 1 is sufficient to collect data from each processing section. Therefore, for example, some of the smart meters 1 in a processing section can be configured to be capable of transmitting power failure notifications, and the other smart meters 1 can be configured not to transmit power failure notifications. Consequently, the number of smart meters 1 including a battery can be reduced, and the smart meter system can be constructed inexpensively.

The configurations described in the above-mentioned embodiment indicate examples of the contents of the present invention. The configurations can be combined with another well-known technique, and some of the configurations can be omitted or changed in a range not departing from the gist of the present invention.

### REFERENCE SIGNS LIST

1-1 to 1-13 smart meter; 2 concentrator; 3 multi-hop network; 4 mobile network; 5 PLC concentrator; 6 PLC network; 7 HES; 8 MDMS; 10 phase group estimation device; 11 data acquirer; 12 aggregator; 13 phase group estimator; 14 event analysis unit; 15 storage.

1. A phase group estimation device comprising:
a data acquirer to acquire data transmitted from a measuring device capable of measuring a voltage of a first distribution line;
a storage to store equipment information indicating a correspondence between the measuring device and an instrument connected to the first distribution line corresponding to the measuring device and connected to a second distribution line; and
a phase group estimator to classify processing sections into phase groups based on the equipment information and the data, each of the processing sections being a section corresponding to the instrument, each of the phase groups being a group powered by a same phase of the second distribution line, wherein
the data include an event notification for giving notice of an event that is a power failure or a voltage drop detected by the measuring device,
the voltage of the first distribution line is obtained by converting a voltage of the second distribution line that is a high-voltage distribution line by a pole-mounted transformer, and
the phase group estimator classifies the processing sections into the phase groups based on information indicating a time of occurrence of the event.

2. The phase group estimation device according to claim 1, wherein the phase group estimator divides the processing sections into processing groups including a plurality of the processing sections, and classifies the processing sections in each processing group into the phase groups.

3. The phase group estimation device according to claim 2, wherein the phase group estimator divides the processing sections into higher-level processing groups including more processing sections than the processing groups, and uses a result of classification of each of the processing groups into the phase groups to classify the processing sections in each of the higher-level processing groups into the phase groups.

4. The phase group estimation device according to claim 1, wherein the phase group estimator reflects, in a result of classification into the phase groups, connected phase information about the processing section that has a known connection to a phase.

5. The phase group estimation device according to claim 1, wherein
the data include the voltage measured by the measuring device, and
the phase group estimator classifies the processing sections into the phase groups based on temporal voltage fluctuations.

6. The phase group estimation device according to claim 5, wherein when the equipment information is changed, the phase group estimator classifies the processing sections into the phase groups using the data obtained before the change in the equipment information and the data obtained after the change in the equipment information.

7. A phase group estimation device comprising:
a data acquirer to acquire data transmitted from a measuring device capable of measuring a voltage of a first distribution line;
a storage to store equipment information indicating a correspondence between the measuring device and an instrument connected to the first distribution line corresponding to the measuring device and connected to a second distribution line; and
a phase group estimator to classify processing sections into phase groups based on the equipment information and the data without using a result of measurement in the second distribution line, each of the processing sections being a section corresponding to the instrument, each of the phase groups being a group powered by a same phase of the second distribution line, wherein
the data include the voltage measured by the measuring device,
the voltage of the first distribution line is obtained by converting a voltage of the second distribution line that is a high-voltage distribution line by a pole-mounted transformer, wherein the phase group estimator classifies the processing sections into the phase groups based on temporal voltage fluctuations, and
when a power failure is expected to happen within a certain area, the phase group estimator excludes the certain area from the classification into the phase groups for an expected period of the power failure.

8. (canceled)

9. The phase group estimation device according to claim 1, comprising a position estimator to estimate a location of a disconnection based on an event notification for giving notice of an event that is a power failure or a voltage drop detected by the measuring device.

10. The phase group estimation device according to claim 1, wherein the measuring device is a meter-reading device for automatic meter reading.

11. The phase group estimation device according to claim 1, wherein the instrument is a transformer that converts a voltage in the second distribution line to a voltage in the first distribution line.

12. A phase group estimation method comprising:
acquiring, by a data acquirer, data transmitted from a measuring device capable of measuring a voltage of a first distribution line;
storing, by a storage, equipment information indicating a correspondence between the measuring device and an instrument connected to the first distribution line corresponding to the measuring device and connected to a second distribution line; and
classifying, by a phase group estimator, processing sections into phase groups based on the equipment information and the data, each of the processing sections being a section corresponding to the instrument, each of the phase groups being a group powered by a same phase of the second distribution line, wherein
the data include an event notification for giving notice of an event that is a power failure or a voltage drop detected by the measuring device,
the voltage of the first distribution line is obtained by converting a voltage of the second distribution line that is a high-voltage distribution line by a pole-mounted transformer, and
in the classifying, the processing sections are classified into the phase groups based on information indicating a time of occurrence of the event.

13. A non-transitory computer readable medium storing therein a phase group estimation program that causes a computer to execute the phase group estimation method according to claim 12.
